(19) United States
(12) Patent Application Publication
(10) Pub. No.: US 2012/0126874 A1
(43) Pub. Date: May 24, 2012

(54) INTEGRATED CIRCUIT

(76) Inventor: Hong-Sok CHOI, Gyeonggi-do (KR)

(21) Appl. No.: 12/980,697

(22) Filed: Dec. 29, 2010

(30) Foreign Application Priority Data
Nov. 22, 2010 (KR) 10-2010-0116143

(51) Int. Cl. H03L 5/00; H01L 25/00

(52) U.S. Cl. 327/333; 327/566

(57) ABSTRACT

An integrated circuit includes a transfer unit configured to transfer an input signal having a first swing width between a first voltage and a second voltage, a driving unit configured to drive an output terminal to output an output signal having a second swing width in response to the input signal transferred from the transfer unit, and a control unit configured to control the driving unit in response to the output signal.

### CROSS-REFERENCE TO RELATED APPLICATIONS

The present application claims priority of Korean Patent Application No. 10-2010-0116143, filed on Nov. 22, 2010, which is incorporated herein by reference in its entirety.

### BACKGROUND OF THE INVENTION

Exemplary embodiments of the present invention relate to a semiconductor device, and more particularly, to an integrated circuit for controlling the swing width of an input signal and outputting the input signal with a changed swing width.

In general, semiconductor devices, such as a Double Data Rate Synchronous Dynamic Random Access Memory (DDR SDRAM) device, include diverse internal circuits. Among them is an internal circuit which receives a signal having a swing width between a supply voltage and a ground voltage, controls the swing width, and outputs the input signal with a swing width between a high pumping voltage and a low pumping voltage. Herein, the high pumping voltage is a voltage higher than the supply voltage, and the low pumping voltage is a voltage lower than the ground voltage. This operation is generally called a voltage level shifting operation, and the integrated circuit performing the voltage level shifting operation is referred to as a voltage level shifting circuit.

FIG. 1 is a circuit diagram of a known voltage level shifting circuit.

Referring to FIG. 1, the voltage level shifting circuit includes a first voltage level shifter 110 and a second voltage level shifter 120.

The first voltage level shifter 110 receives an input signal IN which swings between a supply voltage VDD and a ground voltage VSS and generates a first output signal OUT1 which swings between a high pumping voltage VPP and the ground voltage VSS. The second voltage level shifter 120 receives the first output signal OUT1 and generates a second output signal OUT2 which swings between the high pumping voltage VPP and a low pumping voltage VBB.

FIG. 2 is a waveform diagram describing an operation of the voltage level shifting circuit shown in FIG. 1.

Referring to FIG. 2, an input signal IN swings between a supply voltage VDD and a ground voltage VSS, a first output signal OUT1 swings between a high pumping voltage VPP and the ground voltage VSS, and the second output signal OUT2 swings between the high pumping voltage VPP and a low pumping voltage VBB. Therefore, the voltage level shifting circuit receives the input signal IN which swings between the supply voltage VDD and the ground voltage VSS and generates the second output signal OUT2 which swings between the high pumping voltage VPP and the low pumping voltage VBB.

As shown in FIG. 1, the known voltage level shifting circuit includes the first voltage level shifter 110 and the second voltage level shifter 120. Herein, the first voltage level shifter 110 performs a voltage level shifting operation from the supply voltage VDD to the high pumping voltage VPP, and the second voltage level shifter 120 performs a voltage level shifting operation from the ground voltage VSS to the low pumping voltage VBB. In short, the conventional voltage level shifting circuit primarily raises a pull-up voltage level and then secondarily raises a pull-down voltage level. However, performing the primary and secondary voltage level shifting operations in accordance with the known voltage level shifting circuit cause delaying the operation speed of a circuit employing the voltage level shifting circuit.

Referring back to FIGS. 1 and 2, the time taken for the first voltage level shifter 110 to generate the first output signal OUT1 from the input signal IN is a first delay time tD1 and the time taken for the second voltage level shifter 120 to generate the second output signal OUT2 from the first output signal OUT1 is a second delay time tD2.

As shown in FIG. 2, the time taken to generate the second output signal OUT2 which swings between the high pumping voltage VPP and the low pumping voltage VBB from the input signal IN which swings between the supply voltage VDD and the ground voltage VSS is a sum of the first delay time tD1 and the second delay time tD2. Accordingly, the known voltage level shifting circuit consumes a certain length of time during the voltage level shifting operation, and thus, reduces the operation speed of a circuit using the known voltage level shifting circuit.

### SUMMARY OF THE INVENTION

Exemplary embodiments of the present invention are directed to an integrated circuit that may reduce the time taken to perform a voltage level shifting operation.

In accordance with an exemplary embodiment of the present invention, an integrated circuit includes a transfer unit configured to transfer an input signal having a first swing width between a first voltage and a second voltage, a driving unit configured to drive an output terminal to output an output signal having a second swing width in response to the input signal transferred from the transfer unit, and a control unit configured to control the driving unit in response to the output signal.

The transfer unit may include a first transferor configured to transfer the input signal having the first voltage to the driving unit, and a second transferor configured to transfer the input signal of the second voltage to the driving unit. The second transferor may cut off the input signal in a duration where the input signal is transferred through the first transferor.

In accordance with another exemplary embodiment of the present invention, an integrated circuit includes a first MOS transistor configured to include a source-drain path formed between a first node to which an input signal is inputted and a second node and receive a first voltage at its gate, a second MOS transistor configured to include a source-drain path formed between the first node and a third node and receive a second voltage at its gate, a third MOS transistor configured to include a source-drain path formed between a terminal having a third voltage and an output terminal and have a gate coupled with the second node, a fourth MOS transistor configured to include a source-drain path formed between a terminal having a fourth voltage and the output terminal and have a gate coupled with the third node, a fifth MOS transistor configured to include a source-drain path formed between a terminal having the third voltage and the second node and have a gate coupled with the output terminal, and a sixth MOS transistor configured to include a source-drain path formed between a terminal having the fourth voltage and the third node and have a gate coupled with the output terminal.

### BRIEF DESCRIPTION OF THE DRAWINGS

FIG. 1 is a circuit diagram illustrating a known voltage level shifting circuit.

FIG. 2 is a waveform diagram illustrating an operation of the voltage level shifting circuit shown in FIG. 1.

FIG. 3 is a circuit diagram illustrating a voltage level shifting circuit in accordance with an exemplary embodiment of the present invention.

FIG. 4 is a waveform diagram illustrating an operation of the voltage level shifting circuit shown in FIG. 3.

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

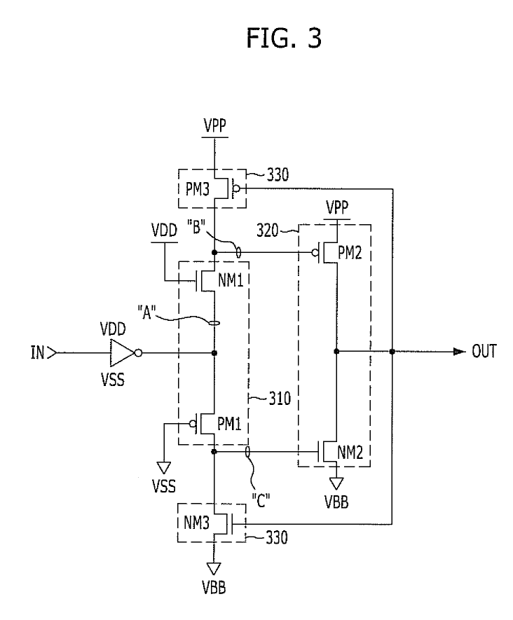

FIG. 3 is a circuit diagram illustrating a voltage level shifting circuit in accordance with an exemplary embodiment of the present invention.

Referring to FIG. 3, the voltage level shifting circuit includes a transfer unit 310, a driving unit 320, and a control unit 330.

The transfer unit 310 transfers an input signal IN having a first swing width between a supply voltage VDD and a ground voltage VSS. The transfer unit 310 includes a first NMOS transistor NM1 and a first PMOS transistor PM1. The first NMOS transistor NM1 includes a source-drain path formed between a first node A and a second node B. The first NMOS transistor NM1 receives an inverted signal of the input signal IN at the first node A, and receives the supply voltage VDD at its gate. The first PMOS transistor PM1 includes a source-drain path formed between the first node A and a third node C. The first PMOS transistor PM1 receives an inverted signal of the input signal IN at the first node A, and receives the ground voltage VSS at its gate.

The driving unit 320 drives an output terminal and outputs an output signal OUT having a second swing width between a high pumping voltage VPP and a low pumping voltage VBB in response to signals transferred from the transfer unit 310 to the second node B and the third node C. The driving unit 320 includes a second PMOS transistor PM2 and a second NMOS transistor NM2. The second PMOS transistor PM2 includes a source-drain path formed between the high pumping voltage VPP and the output terminal, and its gate is coupled with the second node B. The second NMOS transistor NM2 includes a source-drain path formed between the low pumping voltage VBB and the output terminal, and its gate is coupled with the third node C.

The control unit 330 controls the driving unit 320 in response to the output signal OUT. The control unit 330 includes a third PMOS transistor PM3 and a third NMOS transistor NM3. The third PMOS transistor PM3 includes a source-drain path formed between the high pumping voltage VPP and the second node B, and receives the output signal OUT at its gate. The third NMOS transistor NM3 includes a source-drain path formed between the low pumping voltage VBB and the third node C, and receives the output signal OUT at its gate.

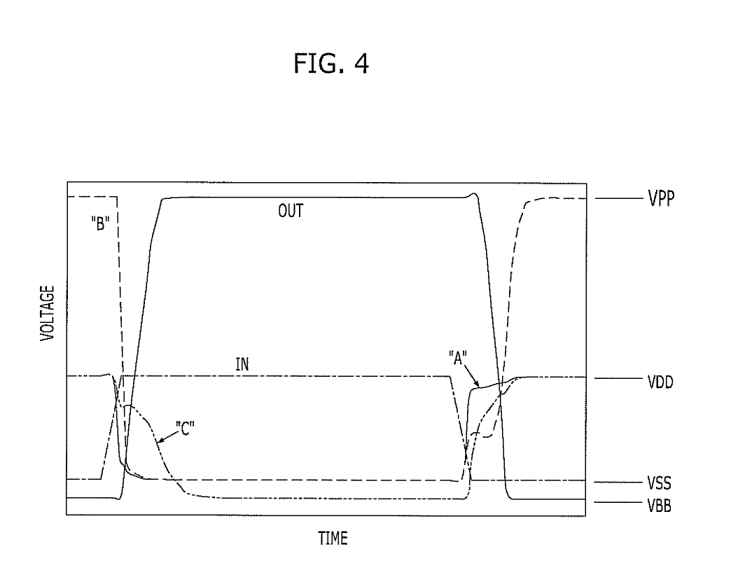

FIG. 4 is a waveform diagram illustrating an operation of the voltage level shifting circuit shown in FIG. 3. The waveforms of the input signal IN, the first to third nodes A, B, and C, and the output signal OUT are shown in the drawing.

First, a case in which the input signal IN transitions from a logic low level to a logic high level is described. Here, the logic low level corresponds to the ground voltage VSS, and the logic high level corresponds to the supply voltage VDD.

When the input signal IN is at a logic high level, the voltage of the first node A becomes the ground voltage VSS, which corresponds to the logic level of an inverted signal of the input signal IN, and the ground voltage VSS is transferred to the second node B through the first NMOS transistor NM1 of the transfer unit 310. Here, the first PMOS transistor PM1 of the transfer unit 310 cuts off the signal inputted through the first node A. Therefore, when the first node A is driven with the ground voltage VSS, a current path may be prevented from being formed between the ground voltage VSS terminal and the low pumping voltage VBB terminal.

Meanwhile, the second PMOS transistor PM2 of the driving unit 320 pull-up drives the output terminal with the high pumping voltage VPP in response to the second node B which is driven with the ground voltage VSS. In other words, the second PMOS transistor PM2 becomes a pull-up driver, and thus, the voltage of the output signal OUT becomes the high pumping voltage VPP. Subsequently, the third NMOS transistor NM3 of the control unit 330 is turned on in response to the output signal OUT which is pull-up driven with the high pumping voltage VPP, and the third node C is driven with the low pumping voltage VBB. Therefore, the second NMOS transistor NM2 of the driving unit 320 is completely turned off (i.e., the second NMOS transistor NM2 of the driving unit 320 is disabled).

Next, a case in which the input signal IN transitions from a logic high level to a logic low level is described.

When the input signal IN is at a logic low level, the voltage of the first node A becomes the supply voltage VDD which is the logic level of the inverted signal of the input signal IN, and the supply voltage VDD is transferred to the third node C through the first PMOS transistor PM1. Here, the first NMOS transistor NM1 cuts off the signal inputted through the first node A. Therefore, as described above, when the first node A is driven with the supply voltage VDD, a current path may be prevented from being formed between the supply voltage VDD terminal and the high pumping voltage VPP terminal.

Meanwhile, the second NMOS transistor NM2 of the driving unit 320 pull-down drives the output terminal with the low pumping voltage VBB in response to the third node C which is driven with the supply voltage VDD. In other words, the second NMOS transistor NM2 becomes a pull-down driver, and thus, the voltage of the output signal OUT becomes the low pumping voltage VBB. Subsequently, the third PMOS transistor PM3 of the control unit 330 is turned on in response to the output signal OUT which is pull-down driven with the low pumping voltage VBB, and the second node B is driven with the high pumping voltage VPP. Therefore, the second PMOS transistor PM2 of the driving unit 320 is completely turned off.

As described above, the integrated circuit in accordance with an exemplary embodiment of the present invention may receive the input signal IN having a swing width between the supply voltage VDD and the ground voltage VSS and generate the output signal OUT having a swing width between the high pumping voltage VPP and the low pumping voltage VBB through one procedural step. This signifies that the voltage level shifting operation may be performed relatively fast, and the overall operation speed of a circuit employing the integrated circuit fabricated in accordance with an exemplary embodiment of the present invention may be increased.

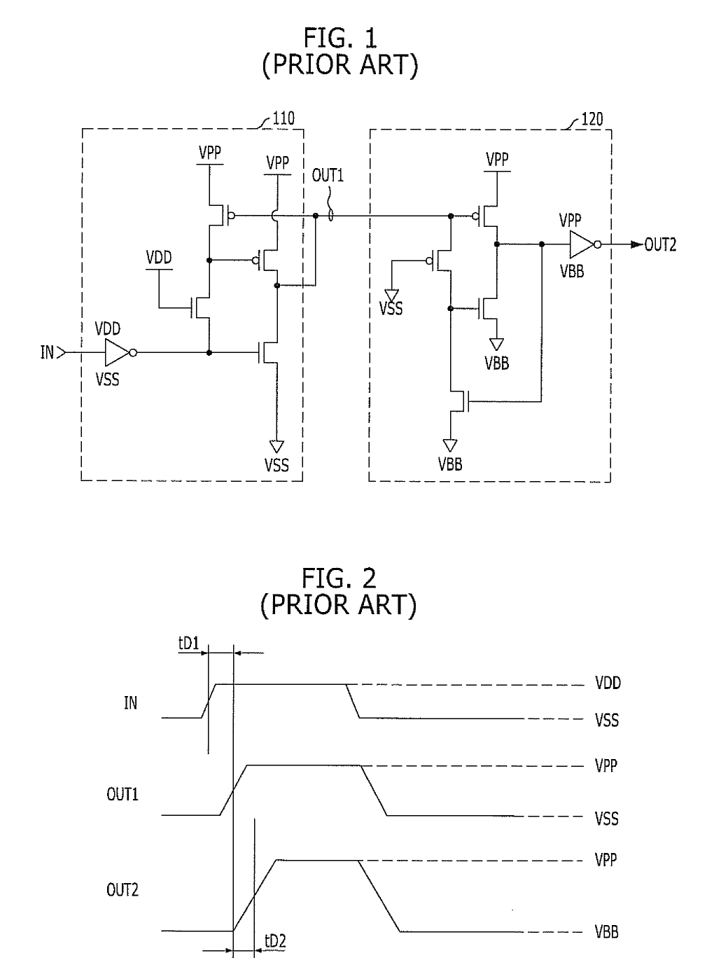

Also, the known voltage level shifting circuit shown in FIG. 1 uses 8 MOS transistors in addition to inverters used to input/output signals. However, the voltage level shifting circuit fabricated in accordance with an exemplary embodiment of the present invention, which is shown in FIG. 3, uses 6 MOS transistors, in addition to an inverter used to input a signal. In short, the voltage level shifting circuit fabricated in accordance with an exemplary embodiment of the present invention may occupy less area than the known voltage level shifting circuit.

According to the technology of the present invention, since the voltage level shifting circuit according to an exemplary embodiment of the present invention may perform a voltage level shifting operation fast, the overall operation speed of a circuit employing the voltage level shifting circuit may be improved.

Also, since the number of transistors used in the voltage level shifting circuit is minimized, the area occupied by the voltage level shifting circuit may be minimized as well.

While the present invention has been described with respect to the specific embodiments, it will be apparent to those skilled in the art that various changes and modifications may be made without departing from the spirit and scope of the invention as defined in the following claims.

For example, the logic gates and transistors illustrated in the above embodiment of the present invention may be modified with regards to position and type according to the polarity of the input signal.

What is claimed is:

1. An integrated circuit, comprising:
a transfer unit configured to transfer an input signal having a first swing width between a first voltage and a second voltage;
a driving unit configured to drive an output terminal to output an output signal having a second swing width in response to the input signal transferred from the transfer unit; and
a control unit configured to control the driving unit in response to the output signal.

2. The integrated circuit of claim 1, further comprising an inverter configured to invert a signal and output the inverted signal to the transfer unit as the input signal.

3. The integrated circuit of claim 1, wherein the transfer unit comprises:
a first transferor configured to transfer the input signal having the first voltage to the driving unit; and
a second transferor configured to transfer the input signal having the second voltage to the driving unit.

4. The integrated circuit of claim 3, wherein the second transferor cuts off the input signal in a duration where the input signal is transferred through the first transferor.

5. The integrated circuit of claim 3, wherein the first transferor cuts off the input signal in a duration where the input signal is transferred through the second transferor.

6. The integrated circuit of claim 1, wherein the driving unit comprises:
a pull-up driver configured to pull-up drive the output terminal in response to the input signal of the second voltage; and
a pull-down driver configured to pull-down drive the output terminal in response to the input signal of the first voltage.

7. The integrated circuit of claim 6, wherein the control unit comprises:
a first controller configured to inactivate the pull-down driver in response to the output terminal which is pull-up driven; and
a second controller configured to inactivate the pull-up driver in response to the output terminal which is pull-down driven.

8. The integrated circuit of claim 1, wherein the second swing width is wider than the first swing width.

9. The integrated circuit of claim 1, wherein the second swing width swings between a third voltage having a higher voltage level than the first voltage and a fourth voltage having a lower voltage level than the second voltage.

10. An integrated circuit, comprising:
a first MOS transistor configured to include a source-drain path formed between a first node to which an input signal is inputted and a second node and receive a first voltage at its gate;
a second MOS transistor configured to include a source-drain path formed between the first node and a third node and receive a second voltage at its gate;
a third MOS transistor configured to include a source-drain path formed between a terminal having a third voltage and an output terminal and have a gate coupled with the second node;
a fourth MOS transistor configured to include a source-drain path formed between a terminal having a fourth voltage and the output terminal and have a gate coupled with the third node;
a fifth MOS transistor configured to include a source-drain path formed between a terminal having the third voltage and the second node and have a gate coupled with the output terminal; and
a sixth MOS transistor configured to include a source-drain path formed between a terminal having the fourth voltage and the third node and have a gate coupled with the output terminal.

11. The integrated circuit of claim 10, further comprising an inverter configured to invert a signal and output the inverted signal to the first node as the input signal.

12. The integrated circuit of claim 10, wherein the third voltage is higher than the first voltage, and the fourth voltage is lower than the second voltage.

13. The integrated circuit of claim 10, wherein the input signal has a swing width between the first voltage and the second voltage, and an output signal of the output terminal has a swing width between the third voltage and the fourth voltage.
